(19) United States
(12) Patent Application Publication
(10) Pub. No.: US 2010/0041209 A1
(43) Pub. Date: Feb. 18, 2010

(54) METHOD FOR MANUFACTURING SEMICONDUCTOR DEVICE

(75) Inventor: Kazuyoshi Furukawa, Kanagawa-ken (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/539,336

(22) Filed: Aug. 11, 2009

(30) Foreign Application Priority Data
Aug. 12, 2008 (JP) 2008-207781

(51) Int. Cl. H01L 21/18

(52) U.S. Cl. 438/455; 257/E21.211; 257/E21.328; 257/E21.088

(57) ABSTRACT

A method for manufacturing a semiconductor device, includes: bringing a first major surface of a first substrate into close contact with a second major surface of a second substrate being different in thermal expansion coefficient from the first substrate at a first temperature higher than room temperature; and bonding the first substrate and the second substrate by heating the first substrate and the second substrate to a second temperature higher than the first temperature with the first major surface being in close contact with the second major surface.

### CROSS-REFERENCE TO RELATED APPLICATIONS

This application is based upon and claims the benefit of priority from the prior Japanese Patent Application No. 2008-207781, filed on Aug. 12, 2008; the entire contents of which are incorporated herein by reference.

### BACKGROUND OF THE INVENTION

1. Field of the Invention

This invention relates to a method for manufacturing a semiconductor device.

2. Background Art

Manufacturing of a semiconductor device includes a process for bonding heterogeneous substrates. For example, manufacturing of a semiconductor light emitting element includes a process for bonding a substrate made of GaAs and a substrate made of GaP.

Several bonding methods have been designed to integrally bond two such heterogeneous substrates. These methods typically involve heat treatment.

For example, in methods using a bonding material, such as eutectic bonding, solder bonding, and glass frit bonding, two substrates are heated to melt or soften the bonding material at the bonding interface so that the two substrates are integrated. Subsequently, the substrates are returned to room temperature.

On the other hand, in direct bonding, which is a method using no bonding material, two substrates are brought into close contact at room temperature by the binding force between OH groups, for example. Then, the temperature of the substrates is increased to advance the bonding reaction of the interface so that the two substrates are robustly bonded. Finally, the substrates are returned to room temperature (see, e.g., JP-A-2001-057441(Kokai)).

These conventional methods for bonding substrates made of different materials have the problem of unsuccessful bonding because of the difference in thermal expansion coefficient between the substrates. More specifically, when the temperature is increased or decreased, the substrate having a larger thermal expansion coefficient expands or shrinks more than the substrate having a smaller thermal expansion coefficient. Hence, the bonding interface and the substrates themselves are subjected to a stress, which may cause warpage, delamination, or fracture of the substrates.

### SUMMARY OF THE INVENTION

According to an aspect of the invention, there is provided a method for manufacturing a semiconductor device, including: bringing a first major surface of a first substrate into close contact with a second major surface of a second substrate being different in thermal expansion coefficient from the first substrate at a first temperature higher than room temperature; and bonding the first substrate and the second substrate by heating the first substrate and the second substrate to a second temperature higher than the first temperature with the first major surface being in close contact with the second major surface.

### BRIEF DESCRIPTION OF THE DRAWINGS

FIG. 1 is a schematic diagram illustrating a method for manufacturing a semiconductor device according to a first embodiment of the invention;

FIG. 2 is a flow chart illustrating the method for manufacturing a semiconductor device according to the first embodiment of the invention;

FIG. 3 is a schematic cross-sectional view illustrating the configuration of a semiconductor device manufactured by the method for manufacturing a semiconductor device according to the first embodiment of the invention;

FIGS. 4A to 4D are sequential schematic cross-sectional views illustrating the method for manufacturing a semiconductor device according to the first embodiment of the invention;

FIG. 5 is a schematic diagram illustrating a method for manufacturing a semiconductor device of a first comparative example;

FIG. 6 is a schematic diagram illustrating a method for manufacturing a semiconductor device of a second comparative example;

FIG. 7 is a schematic diagram illustrating an alternative method for manufacturing a semiconductor device according to the first embodiment of the invention;

FIG. 8 is a flow chart illustrating a method for manufacturing a semiconductor device according to a second embodiment of the invention;

FIG. 9 is a schematic diagram illustrating a method for manufacturing a semiconductor device according to a third embodiment of the invention;

FIG. 10 is a flow chart illustrating the method for manufacturing a semiconductor device according to the third embodiment of the invention;

FIG. 11 is a schematic cross-sectional view illustrating the configuration of another semiconductor device manufactured by the method for manufacturing a semiconductor device according to the first embodiment of the invention; and

FIGS. 12A to 12D are sequential schematic cross-sectional views illustrating another method including the method for manufacturing a semiconductor device according to the first embodiment of the invention.

### DETAILED DESCRIPTION OF THE INVENTION

Embodiments of the invention will now be described in detail with reference to the drawings.

In the present specification and drawings, the same elements as those described previously with reference to earlier figures are labeled with like reference numerals, and the detailed description thereof is omitted as appropriate.

### First Embodiment

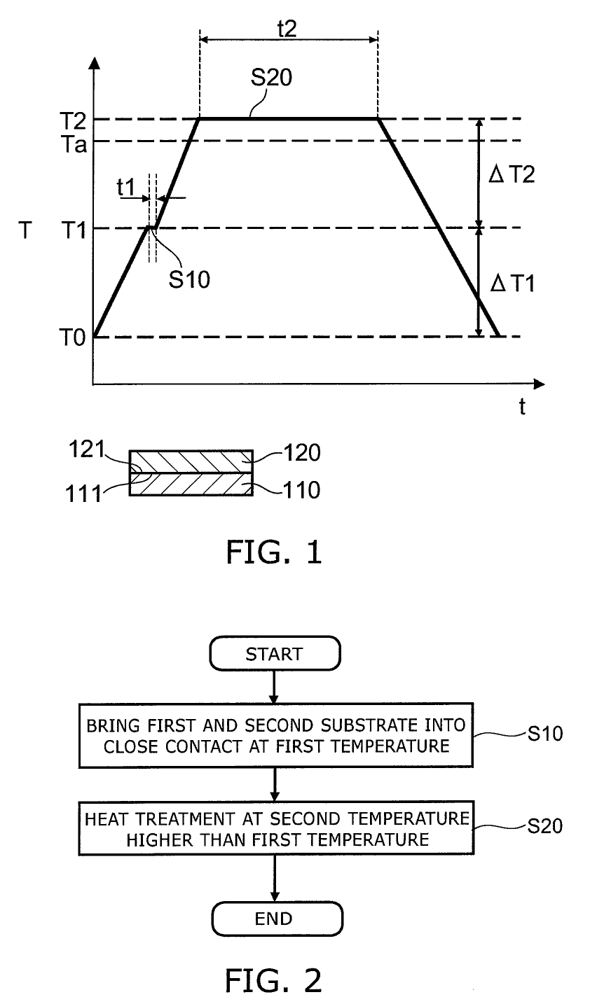

FIG. 1 is a schematic diagram illustrating a method for manufacturing a semiconductor device according to a first embodiment of the invention.

More specifically, this figure illustrates the relationship between substrate temperature and time in the method for manufacturing a semiconductor device according to this embodiment, where the horizontal axis represents time t, and the vertical axis represents substrate temperature T.

FIG. 2 is a flow chart illustrating the method for manufacturing a semiconductor device according to the first embodiment of the invention.

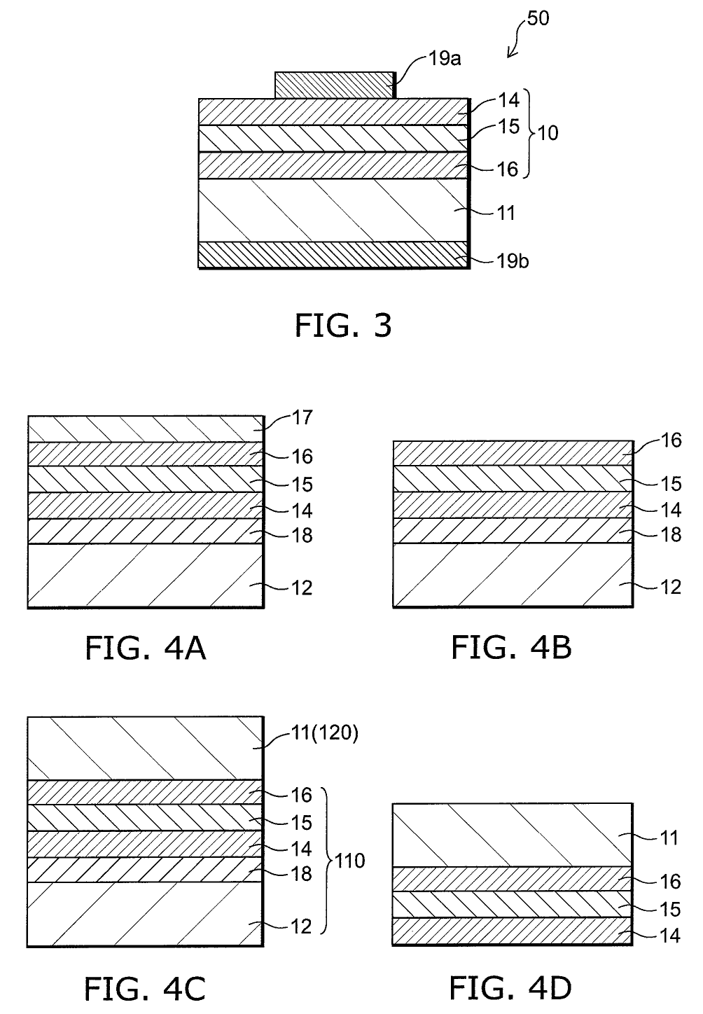

FIG. 3 is a schematic cross-sectional view illustrating the configuration of a semiconductor device manufactured by the method for manufacturing a semiconductor device according to the first embodiment of the invention.

FIG. 4 is a sequential schematic cross-sectional view illustrating the method for manufacturing a semiconductor device according to the first embodiment of the invention.

More specifically, FIG. 4A shows the first step, and FIGS. 4B to 4D respectively show the steps following the previous step. Here, the illustration in FIG. 4 is turned upside down from FIG. 3.

As shown in FIG. 3, the semiconductor device manufactured by the method for manufacturing a semiconductor device according to the first embodiment of the invention is an InGaAlP-based LED 50, for example. As shown in this figure, the LED 50 includes a multilayer body 10 including an active layer 15, and an N-type cladding layer 14 and a P-type cladding layer 16 stacked via this active layer 15; a GaP substrate 11 integrally bonded to the lower surface of this multilayer body 10; a first electrode 19a provided on the upper surface side of the N-type cladding layer 14; and a second electrode 19b provided on the lower surface of the GaP substrate 11.

The multilayer body 10 is formed by epitaxially growing a mixed crystal of compound semiconductor using a GaAs substrate, not shown, as a growth substrate.

The GaP substrate 11 has a major surface, which is the bonding surface bonded to the P-type cladding layer 16. This major surface is mirror-finished, and the multilayer body 10 is directly contact-bonded thereto while it is formed on the aforementioned growth substrate. The growth substrate is removed after contact bonding.

The active layer 15, the N-type cladding layer 14, and the P-type cladding layer 16 have a composition Inₓ(Ga_{1-y}Al_{y})₁₋ₓP, for example.

In this example, the GaP substrate 11 is of P-type and has a thickness of 250 μm (micrometers), for example. The P-type cladding layer 16 has a thickness of 0.6 μm for example, and can have composition ratios of x=0.5 and y=1.0 in the aforementioned composition formula. The active layer 15 has a thickness of 0.6 μm and composition ratios of x=0.5 and y=0.28, for example. The N-type cladding layer 14 has a thickness of 0.6 μm and composition ratios of x=0.5 and y=1.0.

Thus, the LED 50 of this example is formed on the GaP substrate 11 which does not absorb light in the visible region. Hence, the LED 50 can emit light with high brightness.

The LED 50, which is a semiconductor device as described above, can be fabricated by a method as shown in FIG. 4, for example.

First, as shown in FIG. 4A, an epitaxial wafer serving for direct bonding is formed by sequentially stacking a buffer layer 18, an N-type cladding layer 14, an active layer 15, a P-type cladding layer 16, and a surface cover layer 17 on an N-type GaAs substrate 12 (growth substrate). These epitaxial films can be formed by MOCVD (metal organic chemical vapor deposition), for example.

For example, the N-type GaAs substrate 12 can be a substrate having a diameter of 2 inches and a thickness of 250 μm, which is doped with Si at a carrier concentration of approximately 1×10¹⁸/cm³₁ and its major surface is mirror-finished.

The buffer layer 18 can be made of GaAs and have a thickness of 0.5 μm, for example.

The uppermost surface cover layer 17 can be made of GaAs and have a thickness of 0.1 μm, for example.

Next, as shown in FIG. 4B, the aforementioned epitaxial wafer is cleaned, and then etched, for example, by immersion in a liquid mixture of ammonia and hydrogen peroxide solution to remove the surface cover layer 17.

Then, as shown in FIG. 4C, the epitaxial wafer with the surface cover layer 17 removed is directly bonded to the GaP substrate 11. This process uses the manufacturing method according to the first embodiment of the invention, which is described later.

Then, after the epitaxial wafer is bonded to the GaP substrate 11, as shown in FIG. 4D, the GaAs substrate 12 of the aforementioned epitaxial wafer is removed. This removal of the GaAs substrate 12 can be performed, for example, by a method of immersing the bonded body of the epitaxial wafer and the GaP substrate 11 in a liquid mixture of ammonia and hydrogen peroxide solution to selectively etch GaAs. By this etching, the buffer layer 18 is also removed simultaneously.

Then, a first and second electrodes 19a, 19b are provided on the N-type cladding layer 14 and the GaP substrate 11, respectively. Thus, the LED 50 illustrated in FIG. 3 is obtained.

In the following, the process of direct bonding between the epitaxial wafer and the GaP substrate 11 illustrated in FIG. 4C is described in detail. In this process, the surface of the P-type cladding layer 16 formed on the N-type GaAs substrate 12 is directly bonded to the GaP substrate 11. The following description is given assuming that the N-type GaAs substrate 12 and the epitaxial film formed thereon constitute a first substrate 110, and the GaP substrate 11 is a second substrate 120.

As shown in FIGS. 1 and 2, in the method for manufacturing a semiconductor device according to the first embodiment of the invention, first, at a first temperature T1 higher than room temperature T0, the first major surface 111 of the first substrate 110 is brought into close contact with the second major surface 121 of the second substrate 120 being different in thermal expansion coefficient from the first substrate 110 (step S10).

Then, with the first major surface 111 being in close contact with the second major surface 121, the first substrate 110 and the second substrate 120 are heat-treated at a second temperature T2 higher than the first temperature T1 (step S20).

Thus, this embodiment can provide a method for manufacturing a semiconductor device in which heterogeneous substrates are bonded without causing delamination and fracture.

In conventional methods, when two substrates are directly bonded, the two substrates are brought into close contact at room temperature, and then heat-treated.

In contrast, in this embodiment, the first and second substrates 110, 120 are brought into close contact at the first temperature T1 higher than room temperature T0. Subsequently, in this state of close contact, they are heat-treated at the second temperature T2, which is even higher. Then, the temperature is decreased to room temperature T0.

More specifically, as shown in FIG. 1, the step S10 of bringing the two substrates into close contact is performed at the first temperature T1, and the step S20 of heat treatment is performed at the second temperature T2. Here, the difference between room temperature T0 and the temperature for performing step S10 is the temperature difference ΔT1 (=T1−T0). The temperature difference between step S10 and step S20 is ΔT2 (=T2−T1).

Due to the temperature difference ΔT1, a ΔT1-induced stress is applied to the first and second substrate 110, 120. Furthermore, due to the temperature difference ΔT2, a ΔT2-induced stress is applied to the first and second substrate 110, 120. Here, the larger stress of the ΔT1-induced stress and the ΔT2-induced stress governs the delamination and fracture of the substrates. Hence, the delamination and fracture of the substrates can be effectively prevented by decreasing the larger stress of the ΔT1-induced stress and the ΔT2-induced stress so that both the ΔT1-induced stress and the ΔT2-induced stress are made small.

On the other hand, the second temperature T2 can be higher than the temperature Ta required to sufficiently advance the bonding reaction in the two substrates. That is, the difference between room temperature and the second temperature T2 may be relatively large. Here, if the step (step S10) of bringing the substrates into close contact is performed at the first temperature T1 higher than room temperature, then both ΔT1 and ΔT2 can be made relatively small. Thus, the larger stress of the ΔT1-induced stress and the ΔT2-induced stress, which are applied to the substrates due to the difference in thermal expansion coefficient, can be alleviated, and the second temperature T2 can be set to a sufficiently high temperature without causing delamination and fracture.

Thus, this embodiment can provide a method for manufacturing a semiconductor device in which heterogeneous substrates are bonded without causing delamination and fracture.

Hence, the second temperature T2 can be set to a temperature higher than the temperature Ta at which bonding reaction occurs between the first and second substrates 110, 120. For example, when a GaAs substrate and a GaP substrate are bonded, the second temperature T2 can be 350° C. or more, for example.

The aforementioned first temperature T1 can be a temperature higher than room temperature. In that case, preferably, the aforementioned ΔT1 and ΔT2 are substantially equal. That is, preferably, the first temperature T1 is just halfway between the second temperature T2 and room temperature T0.

In practice, the value of the first temperature T1 (° C.) can be 10% to 70% of the second temperature T2 (° C.). Thus, both the aforementioned ΔT1 and ΔT2 can be made relatively small. Consequently, the larger stress of the ΔT1-induced stress and the ΔT2-induced stress can be decreased. Thus, both these thermal stresses can be made small, and delamination, fracture and the like can be avoided.

In the foregoing, the room temperature is 25° C., for example.

In the example shown in FIG. 1, in step S10, the first temperature T1 is retained for a relatively short retention time ti. For example, the retention time ti can be 10 to 60 seconds.

However, the invention is not limited thereto. That is, step S10 can be performed with no retention time at the first temperature T1, while the temperature continues to change. Conversely, the retention time ti of the first temperature T1 may be relatively long, and step S10 may be performed during that time.

In the example shown in FIG. 1, in step S20, the second temperature T2 is retained for a retention time t2 longer than the retention time t1. However, the invention is not limited thereto. That is, the retention time t2 of the second temperature T2 may be relatively short, and step S20 may be performed during that time. Furthermore, the retention time t2 of the second temperature T2 may be substantially very short, and step S20 may be performed while the temperature continues to change. Thus, this embodiment only needs to perform heat treatment at the second temperature T2.

In the foregoing, direct bonding between two substrates is performed as follows.

In direct bonding, two substrates with the surface mirror-finished are brought into close contact in an atmosphere substantially free from foreign matter, and then integrally bonded by heat treatment. In this method, because the entire surface of the substrates is in close contact before heat treatment, the entire surface can be bonded without leaving unbonded portions. Furthermore, because no pressure application is required during heat treatment, this method has the advantage of eliminating the need of special apparatuses or tools. However, pressure may be applied during heat treatment.

In addition to bonding between a GaAs substrate and a GaP substrate described above, this technique for direct bonding is applicable to various substrates.

The bonding mechanism in direct bonding is now described with reference to direct bonding between Si wafers.

First, OH groups are formed at the wafer surface by cleaning or water washing. Then, when the wafer surfaces are brought into contact, OH groups attract each other by hydrogen bonding, and the wafers are brought into close contact even at room temperature. This contact force is strong enough to bring the entire surface into close contact by rectifying typical warpage, if any, of the wafer. During heat treatment, dehydration condensation (Si—OH:HO—Si→Si—O—Si−H₂O) occurs at temperatures exceeding 100° C., and the wafers are bonded together via oxygen atoms, increasing the bonding strength. At even higher temperatures, diffusion and rearrangement of atoms occur in the neighborhood of the bonding interface, and the wafers are integrated electrically as well as in terms of strength. By a similar mechanism, direct bonding also occurs between compound semiconductor substrates or between various substrates and a metal substrate.

In direct bonding, more robust bonding can be realized by sufficiently advancing the aforementioned chemical reaction, or bonding reaction. The temperature Ta required for bonding reaction can be 200° C. or more, for example.

### FIRST COMPARATIVE EXAMPLE

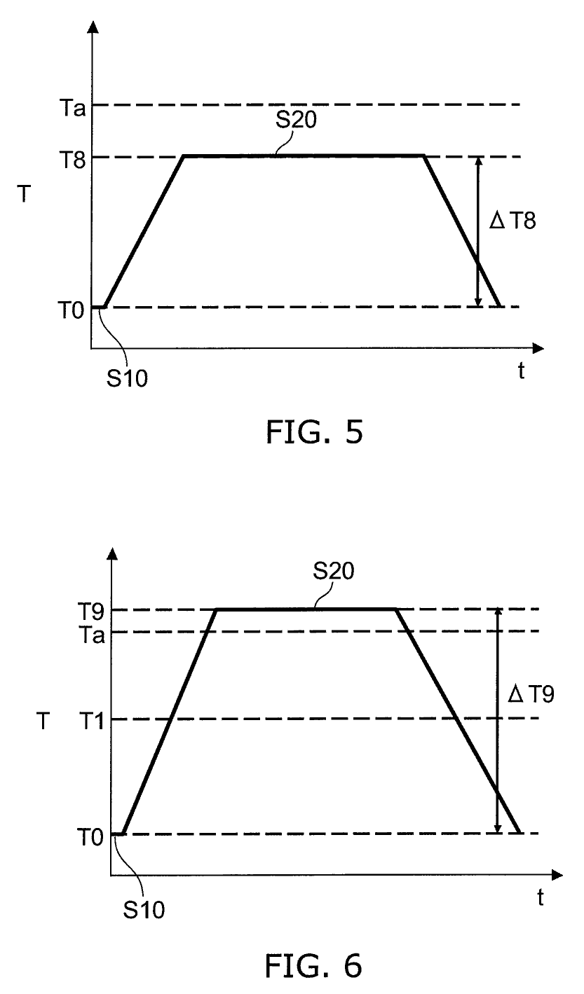

FIG. 5 is a schematic diagram illustrating a method for manufacturing a semiconductor device of a first comparative example.

As shown in FIG. 5, in the method for manufacturing a semiconductor device of the first comparative example, step S10 is performed at room temperature. Furthermore, to reduce thermal stress occurring in heating to a temperature excessively higher than room temperature, the heat treatment temperature T8 is made lower than the temperature Ta required for direct bonding between substrates.

Hence, the temperature difference ΔT8 between room temperature T0 for bringing substrates into close contact and the heat treatment temperature T8 is relatively small.

Thus, in the manufacturing method of the first comparative example, because of the small temperature difference ΔT8, the thermal stress caused thereby is small, and no fracture or slippage occurs in the substrates. However, the heat treatment temperature T8 is lower than the temperature Ta required for direct bonding between substrates. Hence, bonding reaction is insufficient, and the substrate is easily delaminated by treatment with chemicals, for example.

### SECOND COMPARATIVE EXAMPLE

FIG. 6 is a schematic diagram illustrating a method for manufacturing a semiconductor device of a second comparative example.

As shown in FIG. 6, in the method for manufacturing a semiconductor device of the second comparative example, step S10 is performed at room temperature. Furthermore, heat treatment is performed at a heat treatment temperature T9 sufficiently higher than room temperature. This heat treatment temperature T9 is higher than the temperature Ta required for direct bonding between substrates, equal to the second temperature T2 in the above embodiment, for example.

In this case, because the heat treatment temperature T9 is sufficiently high, bonding reaction is sufficiently advanced. Hence, the substrate is not delaminated by treatment with chemicals, for example.

However, the temperature difference ΔT9 between room temperature T0 for bringing substrates into close contact and the heat treatment temperature T9 is very large.

Hence, in the manufacturing method of the second comparative example, because of the large temperature difference ΔT9, the thermal stress caused thereby is large, and fracture or slippage occurs in the substrates.

Thus, in the first and second comparative example, delamination occurs because of insufficient bonding, or fracture or slippage occurs in the substrates.

In contrast, as described above, in this embodiment, substrates are brought into close contact at the first temperature T1 higher than room temperature. Hence, the heat treatment temperature (second temperature T2) can be made sufficiently high while the temperature difference ΔT1 between the temperature for bringing substrates into close contact and room temperature, and the temperature difference ΔT2 between the temperature for bringing substrates into close contact and the second temperature T2 for heat treatment are both made relatively small. Thus, the stress applied to the substrates due to the difference in thermal expansion coefficient can be alleviated, and this embodiment can provide a method for manufacturing a semiconductor device in which heterogeneous substrates are bonded without causing delamination and fracture.

In addition to bonding between a GaAs substrate and a GaP substrate as described above, the method for manufacturing a semiconductor device of this embodiment is applicable to bonding between a pair of wafers which have different thermal expansion each other, such as between various compound semiconductor substrates, and between a silicon substrate and a compound semiconductor. Furthermore, as described above, in addition to direct bonding between substrate surfaces, this embodiment is also applicable to bonding substrates via a metal or other bonding material. Furthermore, this embodiment is applicable to bonding between various substrates, such as bonding between a compound semiconductor or silicon substrate and a metal substrate (or a substrate having a metal layer on the surface). For example, between nitride on sapphire epitaxial wafer coated with Au and Si substrate coated with Au.

When at least one of the first and second substrates 110, 120 is a metal substrate (or a substrate having a metal layer on the surface), the second temperature T2 being the heat treatment temperature, should be lower than the melting point of the metal.

When the first and second substrates 110, 120 are brought into close contact in step S10, the first and second substrates 110, 120 can be pressurized to cause close contact. In particular, when at least one of the first and second substrates 110, 120 is a metal substrate (or a substrate having a metal layer on the surface), bonding force is effectively enhanced by pressurizing the first and second substrates 110, 120 to cause close contact in the step S10 of bringing the substrates into close contact. Since roughness of a metal surface is poor compared with that of crystal wafers surface in general and a microscopic adhesion area on the metal surface is small, a bonding force on the metal surface is week. At the same time, since a metal is soft compared with crystal, microscopic projecting portions on the metal surface become flat by an application of pressure and the microscopic adhesion area increases and the bonding force on the metal surface is increased. However, pressurization is not necessarily needed.

Furthermore, during the heat treatment of the first and second substrates 110, 120 in step S20, the first and second substrates 110, 120 may be heat-treated while being pressurized. However, pressurization is not necessarily needed.

Moreover, in the example shown in FIG. 1, after step S10, the temperature is increased to perform step S20. However, the invention is not limited thereto. After step S10, the temperature may be temporarily decreased, followed by step S20. For example, from the first temperature T1 for step S10, the temperature may be temporarily decreased to room temperature, and then increased to the second temperature T2 for step S20.

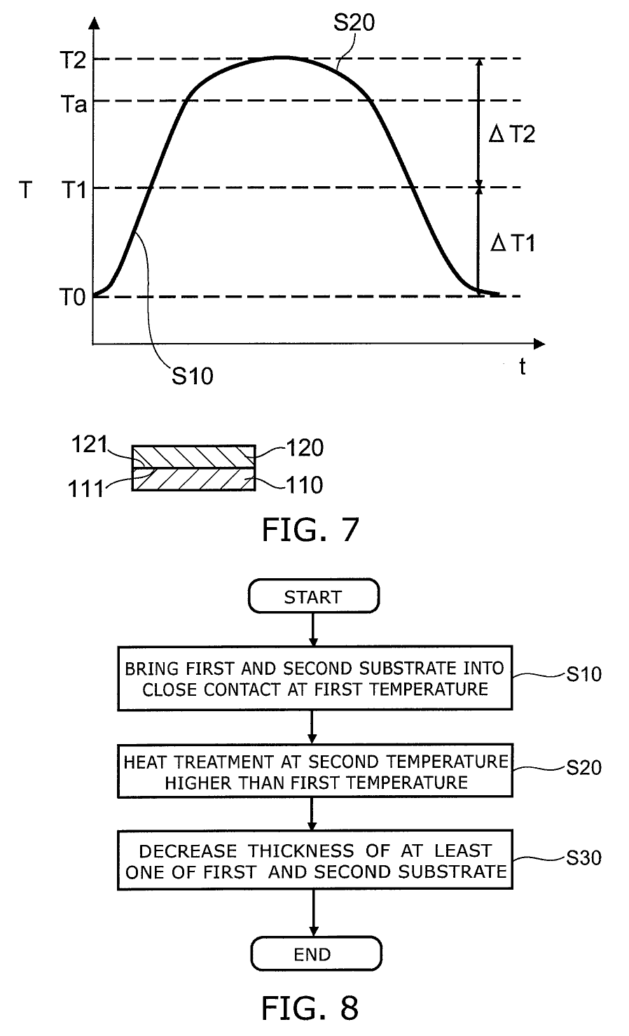

FIG. 7 is a schematic diagram illustrating an alternative method for manufacturing a semiconductor device according to the first embodiment of the invention.

As shown in FIG. 7, also in the alternative method for manufacturing a semiconductor device according to this embodiment, first, at a first temperature T1 higher than room temperature T0, the first major surface 111 of the first substrate 110 is brought into close contact with the second major surface 121 of the second substrate 120 being different in thermal expansion coefficient from the first substrate 110 (step S10). Then, with the first major surface 111 being in close contact with the second major surface 121, the first substrate 110 and the second substrate 120 are heat-treated at a second temperature T2 higher than the first temperature T1 (step S20). However, this method is different from that as shown in FIG. 1 in which the substrate temperature changes linearly and the heat treatment temperature at step S20, for example, is constant at the second temperature T2. In this example, the temperature change is curvilinear. Furthermore, also in the second step S20 for heat treatment, the temperature changes continuously.

Thus, the temperature change of the first and second substrates 110, 120 may be curvilinear, and the temperature during heat treatment may change.

In the embodiments of the invention, the step S20 of heat treatment only needs to be performed at temperatures including at least the second temperature T2.

In this example, the step S10 of bonding substrates is performed at the first temperature T1 while the substrate temperature changes continuously. That is, step S10 may be performed in a prescribed temperature range including the first temperature T1.

### EXAMPLE

In the following, a method for manufacturing a semiconductor device according to a practical example of this embodiment is described.

In the method for manufacturing a semiconductor device according to this practical example, a first substrate 110 made of GaAs and a second substrate 120 made of GaP are bonded. These substrates have a diameter of 100 mm and a thickness of 400 μm.

First, the first and second substrates 110, 120 with the surface mirror-finished were heated to the first temperature T1, 250° C. At 250° C., the major surfaces (front surfaces) of the first and second substrates 110, 120 were opposed to each other and brought into close contact. Subsequently, with the first and second substrates 110, 120 being in close contact, they were heated to the second temperature T2, 500° C. Then, at the second temperature T2, heat treatment was performed for a prescribed time. This heat treatment time is, for example, 60 minutes. Subsequently, the temperature of the substrates was decreased back to room temperature.

No fracture or slippage occurred in the substrates bonded by this method and returned to room temperature.

More specifically, in the method for manufacturing a semiconductor device according to this practical example, the first and second substrates 110, 120 are brought into close contact at the first temperature T1, and heat treatment is performed at the second temperature T2. Hence, the temperature difference between the close contact and the heat treatment is 250° C., which is relatively small. Hence, no fracture or slippage occurs in the substrates during heat treatment.

Furthermore, subsequently, when the temperature is decreased from 500° C. of the heat treatment temperature (second temperature T2), the temperature is first decreased to 250° C. of the first temperature T1, where the first and second substrates 110, 120 are returned to the state at the close contact. Then, the temperature is further decreased and returned to room temperature, 25° C. Here, the temperature is decreased from 250° C. for the close contact to 25° C., with a temperature difference of 225° C. This temperature difference is also relatively small, and hence no fracture or slippage occurred in the substrates.

To confirm the strength of the bonding interface of the substrates, the bonded substrates were immersed in a liquid mixture of ammonia and hydrogen peroxide solution to selectively etch the first substrate 110 (GaAs substrate). Then, etching was successfully performed without delamination of the substrates from the bonding interface until the first substrate 110, or the GaAs substrate, vanished. This indicated that bonding reaction was sufficiently advanced.

Due to the temperature difference between the close contact temperature (250° C.) and room temperature (25° C.), warpage occurred at room temperature with the second substrate 120 (GaP substrate) side being convex. However, this was practically irrelevant.

Thus, in the method for manufacturing a semiconductor device according to this practical example, the substrates are brought into close contact at a high temperature, and then heated at an even higher temperature. This method achieves bonding with sufficient bonding reaction without fracture or slippage in the substrates and delamination during etching.

### THIRD COMPARATIVE EXAMPLE

Also in a method for manufacturing a semiconductor device of a third comparative example, a first substrate 110 made of GaAs and a second substrate 120 made of GaP are bonded. Like the practical example, these substrates have a diameter of 100 mm and a thickness of 400 μm.

First, at room temperature, the first and second substrates 110, 120 with the surface mirror-finished were opposed to each other and brought into close contact. Then, with the first and second substrates 110, 120 being in close contact, the temperature was increased to 300° C. (that is, the heat treatment temperature T8 illustrated in FIG. 5), where heat treatment was performed at 300° C., and returned to room temperature.

By this heat treatment at 300° C., no fracture or warpage occurred in the substrates.

When the bonded substrates were immersed in a liquid mixture of ammonia and hydrogen peroxide solution to selectively etch the first substrate 110 (GaAs substrate), the substrates were delaminated from the bonding interface. Thus, the bonding reaction was insufficient.

### FOURTH COMPARATIVE EXAMPLE

Also in a method for manufacturing a semiconductor device of a fourth comparative example, a first substrate 110 made of GaAs and a second substrate 120 made of GaP are bonded. Again, these substrates have a diameter of 100 mm and a thickness of 400 μm.

First, at room temperature, the first and second substrates 110, 120 with the surface mirror-finished were opposed to each other and brought into close contact. Then, with the first and second substrates 110, 120 being in close contact, the temperature was increased to 500° C. (the heat treatment temperature T9 illustrated in FIG. 6), where heat treatment was performed at 500° C., and returned to room temperature.

By this heat treatment at 500° C., slippage occurred in the bonded second substrate 120 (GaP substrate).

The bonded substrates were immersed in a liquid mixture of ammonia and hydrogen peroxide solution to selectively etch the first substrate 110 (GaAs substrate). Then, etching was successfully performed without delamination of the substrates from the bonding interface until the first substrate 110, or the GaAs substrate, vanished. This indicated that bonding reaction was sufficiently advanced.

Thus, in the first and second comparative examples, the substrates are brought into close contact at room temperature. Here, if the heat treatment temperature is 300° C. as in the first comparative example, the difference between the close contact temperature and room temperature is 275° C. The substrates can resist this temperature difference, and no slippage or the like occurs therein. However, if the heat treatment temperature is 500° C. as in the second comparative example, the difference between the close contact temperature and room temperature is 475° C. The substrates cannot resist this temperature difference, and slippage occurs therein. On the other hand, as in the second comparative example, heat treatment at 500° C., which is 475° C. higher than room temperature, can achieve bonding with sufficient bonding reaction. However, as in the first comparative example, heat treatment at 300° C., which is 275° C. higher than room temperature, results in insufficient bonding.

In contrast, in the method for manufacturing a semiconductor device according to this practical example, when heterogeneous substrates being different in thermal expansion coefficient are integrally bonded, the two substrates are brought into close contact at a first temperature T1 higher than room temperature, that is, the temperature at which the substrates are typically used. Subsequently, while the bonding interface is fixed, heat treatment is performed at a second temperature T2 even higher than the first temperature T1. Thus, robust bonding can be achieved without fracture in the substrates.

### Second Embodiment

FIG. 8 is a flow chart illustrating a method for manufacturing a semiconductor device according to a second embodiment of the invention.

As shown in FIG. 8, in the method for manufacturing a semiconductor device according to the second embodiment of the invention, step S10 and step S20 described in the first embodiment are followed by decreasing the thickness of at least one of the first substrate 110 and the second substrate 120 (step S30).

For example, as shown in FIG. 4C, assume that the N-type GaAs substrate 12 and the epitaxial film formed thereon constitute a first substrate 110, and the GaP substrate 11 is a second substrate 120. After the epitaxial wafer (the N-type GaAs substrate 12 and the epitaxial film formed thereon) and the GaP substrate 11 are bonded by step S10 and step S20, the GaAs substrate 12 and the buffer layer 18 of the aforementioned epitaxial wafer are removed as shown in FIG. 4D. That is, the thickness of the first substrate 110 is decreased by the thickness of the GaAs substrate 12 and the buffer layer 18.

Thus, the LED 50 is formed.

In the method for manufacturing a semiconductor device according to this embodiment, the first and second substrates 110, 120 are stably bonded by step S10 and step S20. Hence, this embodiment can substantially avoid problems of various subsequent processes, for example decreasing the thickness of at least one of the first and second substrates 110, 120, and can achieve stable manufacturing.

Hence, in the method for manufacturing a semiconductor device according to this embodiment, the thickness of the substrate can be adjusted to reduce the possibility of fracture in the substrate, increase various manufacturing margins, and improve the performance of the semiconductor device.

Thus, this embodiment can provide a method for manufacturing a semiconductor device in which heterogeneous substrates are bonded and stable manufacturing is achieved without causing delamination and fracture.

### Third Embodiment

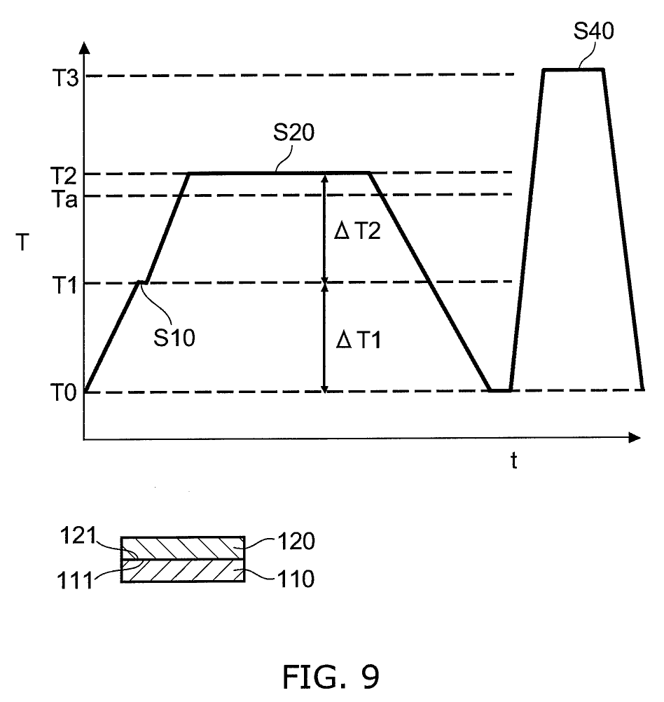

FIG. 9 is a schematic diagram illustrating a method for manufacturing a semiconductor device according to a third embodiment of the invention.

More specifically, this figure illustrates the relationship between substrate temperature and time in the method for manufacturing a semiconductor device according to this embodiment, where the horizontal axis represents time t, and the vertical axis represents substrate temperature T.

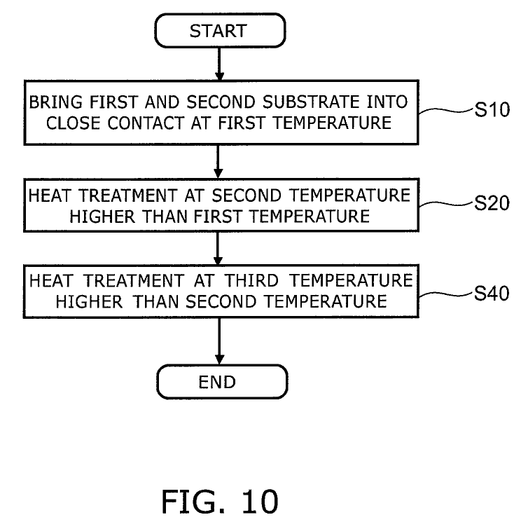

FIG. 10 is a flow chart illustrating the method for manufacturing a semiconductor device according to the third embodiment of the invention.

As shown in FIGS. 9 and 10, in the method for manufacturing a semiconductor device according to the third embodiment of the invention, step S10 and step S20 described in the first embodiment are followed by further heat treatment at a third temperature T3 even higher than the second temperature T2 (step S40).

This higher temperature advances the bonding interface reaction, such as solid phase re-arrangement of atoms and diffusion of interfacial impurity. And the crystal structure of the semiconductor device is made stable and uniform. This improves various electrical characteristics, such as lower and more uniform operating voltage, lower power consumption, higher brightness and higher reliability.

The third temperature T3 can be 600° C. to 800° C., for example.

In the example shown in FIG. 9, the temperature is temporarily decreased to room temperature T0, for example, between step S20 and step S40, and at this room temperature, step S30 described in the second embodiment can be performed.

More specifically, the heat treatment at the second temperature T2 is followed by decreasing the thickness of at least one of the first substrate 110 and the second substrate 120 (step S30). Subsequently, at a third temperature T3 higher than the second temperature T2, the first substrate 110 and the second substrate 120 can be heat-treated (step S40). Thus, thinning or removing the substrate causing thermal stress allows a heat treatment at a higher temperature without occurrence of slippage and fracture.

Thus, for example, by performing the step S40 of heat treatment at the third temperature T3 after removing the GaAs substrate 12 and the buffer layer 18 constituting part of the first substrate 110, the crystal structure of the semiconductor device is made stable and uniform. This improves various electrical characteristics, such as lower and more uniform operating voltage, lower power consumption, higher brightness and higher reliability.

In the third embodiment of the invention, the temperature does not necessarily need to be decreased to room temperature T0, for example, between step S20 and step S40. The temperature may be decreased to a temperature higher than room temperature T0. Alternatively, it is also possible to increase the temperature from the second temperature T2 to the third temperature T3 without decreasing the temperature.

In the case where step S30 is performed between step S20 and step S40, for example, the temperature for step S30 is arbitrary.

Furthermore, it is also possible not to perform step S30 between step S20 and step S40.

Thus, this embodiment can provide a method for manufacturing a semiconductor device with improved electrical characteristics in which heterogeneous substrates are bonded without causing delamination and fracture.

Another specific example of this embodiment will be described.

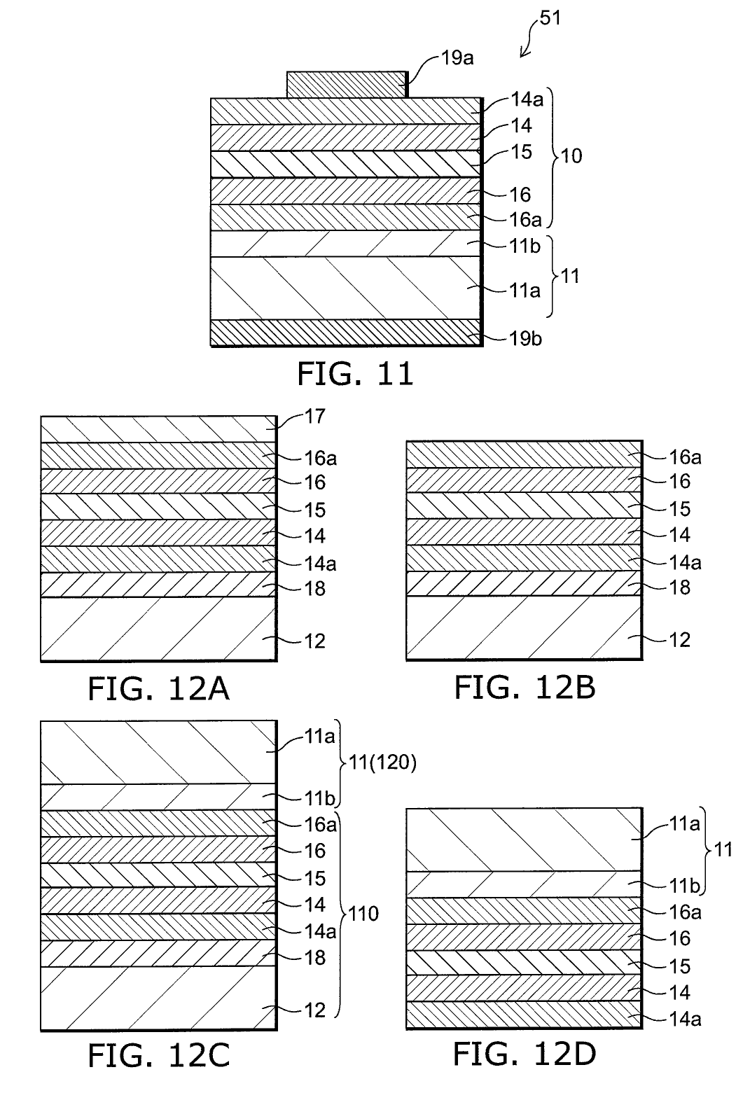

FIG. 11 is a schematic cross-sectional view illustrating the configuration of another semiconductor device manufactured by the method for manufacturing a semiconductor device according to the first embodiment of the invention.

FIGS. 12A to 12D are sequential schematic cross-sectional views illustrating another method including the method for manufacturing a semiconductor device according to the first embodiment of the invention.

As shown in FIG. 11, in the LED 51 being another semiconductor device manufactured by the method for manufacturing a semiconductor device according to the first embodiment, the multilayer body 10 further includes a first bonding layer 16a and an N-type current spreading layer 14a. The GaP substrate 11 includes a GaP layer 11a and a second bonding layer 11b. The configuration other than those is the same as that of the LED 50 described previously, and hence the description thereof is omitted.

The first bonding layer 16a is provided on a side of the P-type cladding layer 16 opposite to the active layer 15. The first bonding layer 16a is, for example, based on P-type InGaP having a thickness of, for example, 0.5 μm. The first bonding layer 16a is opposed to the second bonding layer 11b.

The N-type current spreading layer 14a is provided on a side of the N-type cladding layer 14 opposite to the active layer 15. The N-type current spreading layer 14a is, for example, based on Inₓ(Ga_{1-y}Al_{y})₁₋ₓ having a thickness of, for example, 5 μm. The first electrode 19a is provided on the N-type current spreading layer 14a.

The second bonding layer 11b is provided on a side of the GaP substrate 11 opposite to the multilayer body 10 and is, for example, a layer containing impurities of high concentration. This allows the resistance to be decreased. The second bonding layer 11b is, for example, a GaP or InGaP layer containing Zn of 1×10¹⁸/cm³. The second bonding layer 11b can be formed by diffusing impurities of high concentration into the GaP layer 11a, ion implantation of high concentration into the GaP layer 11a or epitaxially growing a doped layer of high concentration on the GaP layer 11aa. The second bonding layer 11b has a thickness of, for example, 0.5 μm. Here, in this specific example, the second bonding layer 11b is P-type.

Thickness of the second bonding layer 11b is for example, 0.5 μm.

Here, as described above, the GaP substrate 11 includes the second bonding layer 11b formed on the major surface of the GaP layer 11a which is mirror-finished by various methods, and the surface of the GaP substrate 11 (surface of second bonding layer 11b) in this case is also mirror surface. Thus, in the specification, “mirror surface” includes a surface of layer formed on mirror-finished surfaces by various methods in addition to a mirror-finished surface.

The LED 51 like this can be fabricated by the method illustrated in FIGS. 12A to 12D, for example.

First, as shown in FIG. 12A, the buffer layer 18, the N-type current spreading layer 14a, the N-type cladding layer 14, the active layer 15, the P-type cladding layer 16, the first bonding layer 16a and the surface cover layer 17 are sequentially stacked on the N-type GaAs substrate 12. These epitaxial films can be formed also using, for example, the MOCVD method. These substrates, the material and thickness of each layer are the same as described previously.

Next, as shown in FIG. 12B, the surface cover layer 17 is removed using the method described with regard to FIG. 4B.

As shown in FIG. 12C, the epitaxial wafer having the surface cover layer 17 removed (N-type GaAs substrate 12, buffer layer 18, N-type current spreading layer 14a, N-type cladding layer 14, active layer 15, P-type cladding layer 16 and first bonding layer 16a) is directly bonded to the GaP substrate 11 (GaP layer 11a and second bonding layer 11b). At this time, the manufacturing methods described with regard to the first to third embodiments of the invention are used. That is, the above epitaxial wafer is a first substrate 110, and the GaP substrate 11 is a second substrate 120. At this time, bonding is performed with the first bonding layer 16a facing the second bonding layer 11b. That is, the first major surface is the surface of the first bonding layer 16a, and the second major surface is the surface of the second bonding layer 11b. Thus, the GaP substrate 11 (second substrate) is provided on the second major surface side, and can include the second bonding layer 11b (bonding layer) including any one of GaP and InGaP. This bonding layer is a layer containing impurities of high concentration.

As shown in FIG. 12D, after the epitaxial wafer is bonded to the GaP substrate 11, the GaAs substrate 12 and the buffer layer 18 are removed by the method described with regard to FIG. 4D.

The first and second electrodes 19a, 19b are provided on the N-type current spreading layer 14a and the GaP substrate 11, respectively, and then the LED 51 illustrated in FIG. 11 can be manufactured.

Also in this case, the same effects described with regard to the first to third embodiments are obtained. That is, heterogeneous substrates are bonded without causing delamination and fracture.

The embodiments of the invention have been described with reference to examples. However, the invention is not limited to these examples. For instance, various specific configurations of the components constituting the method for manufacturing a semiconductor device are encompassed within the scope of the invention as long as those skilled in the art can similarly practice the invention and achieve similar effects by suitably selecting such configurations from conventionally known ones.

Furthermore, any two or more components of the examples can be combined with each other as long as technically feasible, and such combinations are also encompassed within the scope of the invention as long as they fall within the spirit of the invention.

Furthermore, those skilled in the art can suitably modify and implement the method for manufacturing a semiconductor device described above in the embodiments of the invention, and all the methods for manufacturing a semiconductor device thus modified are also encompassed within the scope of the invention as long as they fall within the spirit of the invention.

Furthermore, those skilled in the art can conceive various modifications and variations within the spirit of the invention, and it is understood that such modifications and variations are also encompassed within the scope of the invention.

1. A method for manufacturing a semiconductor device, comprising:
bringing a first major surface of a first substrate into close contact with a second major surface of a second substrate being different in thermal expansion coefficient from the first substrate at a first temperature higher than room temperature; and
bonding the first substrate and the second substrate by heating the first substrate and the second substrate to a second temperature higher than the first temperature with the first major surface being in close contact with the second major surface.

2. The method according to claim 1, wherein
the first temperature is lower than a temperature at which the first substrate and the second substrate are substantially bonded, and
the second temperature is higher than the temperature at which the first substrate and the second substrate are substantially bonded.

3. The method according to claim 1, wherein the first temperature (° C.) is 30% to 70% of the second temperature (° C.).

4. The method according to claim 1, further comprising:
decreasing thickness of at least one of the first substrate and the second substrate after the bonding.

5. The method according to claim 4, further comprising:
heat-treating the first substrate and the second substrate at a third temperature higher than the second temperature after the decreasing thickness of at least one of the first substrate and the second substrate.

6. The method according to claim 1, further comprising:
heat-treating the first substrate and the second substrate at a third temperature higher than the second temperature after the bonding.

7. The method according to claim 6, wherein the third temperature is a temperature in a range from 600° C. to 800° C.

8. The method according to claim 1, wherein the first substrate is one of a silicon wafer, a compound semiconductor substrate, and a metal substrate, and the second substrate is one of a silicon wafer, a compound semiconductor substrate, and a metal substrate.

9. The method according to claim 1, wherein at least one of the first major surface and the second major surface is an epitaxial growth film surface.

10. The method according to claim 1, wherein the first substrate includes an N-type semiconductor layer made of Inₓ₋₁(Ga_{1-y1}Al_{y1})₁₋ₓ₁P (0≦x1≦1, 0≦y1≦1), an active layer stacked on the N-type semiconductor layer and made of Inₓ₂(Ga_{1-y2}Al_{y2})₁₋ₓ₂P (0≦x2≦1, 0≦y2≦1), and a P-type semiconductor layer stacked on a surface of the active layer opposite to the N-type semiconductor layer and made of Inₓ₃(Ga_{1-y3}Al_{y3})₁₋ₓ₃P (0≦x3≦1, 0≦y3≦1).

11. The method according to claim 10, wherein the N-type semiconductor layer is formed on a GaAs substrate via a buffer layer.

12. The method according to claim 10, wherein the first major surface is a surface of the P-type semiconductor layer opposite to the active layer.

13. The method according to claim 10, wherein the second substrate includes a GaP layer.

14. The method according to claim 13, wherein the GaP layer includes a bonding layer provided on a side of the second main surface and including at least one of GaP and InGaP.

15. The method according to claim 10, wherein the second temperature is 350° C. or more.

16. The method according to claim 1, wherein the bonding the first substrate and the second substrate includes pressurizing the first substrate and the second substrate to each other.

17. The method according to claim 1, wherein time retained at the first temperature is shorter than time retained at the second temperature.

18. The method according to claim 1, wherein temperature of the first substrate and the second substrate changes continuously with time.

19. The method according to claim 1, wherein the bonding the first substrate and the second substrate is performed while temperature of the first substrate and the second substrate changes continuously.

20. The method according to claim 1, wherein the first major surface and the second major surface are mirror surface.
